(19) United States
(12) Patent Application Publication
(10) Pub. No.: US 2014/0138044 A1
(43) Pub. Date: May 22, 2014

(54) COOLING SYSTEM

(71) Applicants: Yoshiaki Kawakami, Nagoya-shi (JP); Yuki Jojima, Nagoya-shi (JP); Eizo Takahashi, Chiryu-shi (JP); Kousuke Sato, Toyota-shi (JP); Yuichi Ohno, Nishio-shi (JP); Kazuhide Uchida, Hamamatsu-shi (JP)

(72) Inventors: Yoshiaki Kawakami, Nagoya-shi (JP); Yuki Jojima, Nagoya-shi (JP); Eizo Takahashi, Chiryu-shi (JP); Kousuke Sato, Toyota-shi (JP); Yuichi Ohno, Nishio-shi (JP); Kazuhide Uchida, Hamamatsu-shi (JP)

(73) Assignee: TOYOTA JIDOSHA KABUSHIKI KAISHA, Toyota-shi, Aichi-ken (JP)

(21) Appl. No.: 14/130,130

(22) PCT Filed: Aug. 7, 2012
(86) PCT No.: PCT/IB2012/001506

§ 371 Date: Dec. 30, 2013

(30) Foreign Application Priority Data
Aug. 8, 2011 (JP) 2011-172866

(51) Int. Cl. H05K 7/20

(52) U.S. Cl. CPC H05K 7/2029
USPC 165/11.1; 165/104.31; 165/104.21

(57) ABSTRACT

A cooling system for cooling a heat generation source includes a cooling unit that is configured to cool the heat generation source by a coolant flowing through the cooling unit, a heat exchanger that is configured to perform heat exchange between the coolant and outside air, a liquid storage device that is configured to store the coolant in a liquid state, a first passage for the coolant that connects between the heat exchanger and the liquid storage device, a second passage for the coolant that connects between the liquid storage device and the cooling unit, and that includes a main passage that connects between the liquid storage device and the cooling unit and a sub passage, at least part of which is separate from the main passage, a pump that is provided on the sub passage.

### BACKGROUND OF THE INVENTION

1. Field of the Invention

The invention relates to a cooling system, and in particular to a cooling system designed to cool a heat generation source by circulating a coolant to a cooling unit that cools the heat generation source.

2. Description of the Related Art

Vehicles running on drive power generated by electric motors such as hybrid vehicles (HVs), fuel cell vehicles, and electric vehicles are attracting attention as an option to solve environmental problems. Electric equipment in such vehicles, including motors, generators, inverters, converters and batteries generates heat due to exchanges of electric power. Therefore, the electric equipment must be cooled.

Techniques have been proposed in which a steam compression refrigeration cycle that is normally used as a vehicle air-conditioning system is utilized to cool a heat generator. For example, Japanese Patent Application Publication No. 11-23081 (JP 11-23081 A) describes an apparatus which is provided with a cooling unit configured such that an intermediate pressure coolant in a refrigeration cycle cools heat generation equipment, and with electric expansion valves which are arranged upstream and downstream, respectively, of the cooling unit and apertures of which are controllable by external signals, so that heat generation equipment is cooled with the intermediate pressure coolant.

Japanese Patent Application Publication No. 2005-90862 (JP 2005-90862 A) describes a cooling system in which heat generator cooling means for cooling a heat generator is provided on a bypass passage for bypassing a decompressor, an evaporator and a compressor in an air-conditioning refrigeration cycle. Further, Japanese Patent Application Publication No. 2007-69733 (JP 2007-69733 A) describes a system in which a heat exchanger for exchanging heat with air for air conditioning and another heat exchanger for exchanging heat with a heat generator are arranged in parallel on a coolant passage extending from an expansion valve to a compressor, so that the heat generator is cooled by means of a coolant for air-conditioner.

In the cooling systems described in JP 2005-90862 A and JP 2007-69733 A, a cooling passage for cooling a heat generation source such as electric equipment is incorporated in a steam compression refrigeration cycle, and when the heat generation source is to be cooled, a coolant which is in a gas-liquid two-phase state after passing through a decompressor is introduced into a coolant passage for cooling the heat generation source. If the flow rate of the coolant for cooling the heat generation source is reduced, it may possibly lead to deterioration of performance for cooling the heat generation source.

### SUMMARY OF THE INVENTION

The invention provides a cooling system capable of cooling heat generation sources in a stable and reliable manner.

An aspect of the invention relates to a cooling system. The cooling system is for cooling a heat generation source, and includes a cooling unit, a heat exchanger, a liquid storage device, first and second passages for a coolant, a second passage and a pump. The cooling unit is configured to cool the heat generation source by a coolant flowing through the cooling unit. The heat exchanger is configured to perform heat exchange between the coolant and outside air. The liquid storage device is configured to store the coolant in liquid state. The first passage for the coolant connects between the heat exchanger and the liquid storage device. The second passage for the coolant connects between the liquid storage device and the cooling unit, and comprises a main passage that connects between the liquid storage device and the cooling unit and a sub passage, at least part of which is separate from the main passage. The pump is provided on the sub passage.

In the aforementioned aspect, the liquid storage device may function as a gas-liquid separator for separating the coolant into a gas-phase coolant and a liquid-phase coolant.

In the aforementioned aspect, one end of the sub passage may be connected to the liquid storage device and the other end of the sub passage may be connected to the main passage.

In the aforementioned aspect, the cooling system may further include a flow guide unit that is configured to guide a flow direction of the coolant that is discharged from the pump and flows into the main passage, to a direction from the liquid storage device toward the cooling unit.

In the aforementioned aspect, the cooling system may further include an aspirator arranged at a position where the coolant discharged from the pump flows into the first passage. In this aspect, the coolant may flow into the first passage from the sub passage via the aspirator.

In the aforementioned aspect, the cooling system may further include a sensor for acquiring data indicating a state of the coolant after the coolant flows through the cooling unit to cool the heat generation source. In this aspect, the pump may be activated or stopped based on the data.

In the aforementioned aspect, the pump may be stopped if a temperature of the coolant after the coolant flows through the cooling unit to cool the heat generation source is below a predetermined threshold. The pump may be activated when the temperature of the coolant after flowing through the cooling unit to cool the heat generation source is equal to or higher than the predetermined threshold.

The cooling system according to the aspect described above is capable of ensuring a sufficient flow rate of the coolant flowing to a heat generation source, and hence is capable of cooling the heat generation source stably while preventing the deterioration of the cooling capacity for the heat generation source.

### BRIEF DESCRIPTION OF THE DRAWINGS

The features, advantages, and technical and industrial significance of the invention will be described in the following detailed description of example embodiments of the invention with reference to the accompanying drawings, in which like numerals denote like elements, and wherein:

FIG. 1 is a schematic diagram illustrating a configuration of a cooling system;

FIG. 2 is a schematic diagram illustrating in detail a configuration of an aspirator shown in FIG. 1;

FIG. 3 is a flowchart illustrating operation control for a pump;

FIG. 4 is a schematic diagram illustrating in detail a configuration of an aspirator according to a modification example;

FIG. 5 is a schematic cross-sectional view of the aspirator taken along the line V-V in FIG. 4; and

FIG. 6 is a schematic diagram illustrating in detail a configuration of an aspirator according to another modification example.

### DETAILED DESCRIPTION OF EMBODIMENTS

Exemplary preferred embodiments of the invention will be described with reference to the drawings, in which the same or corresponding parts are indicated with the same reference numerals and description thereof will not be repeated.

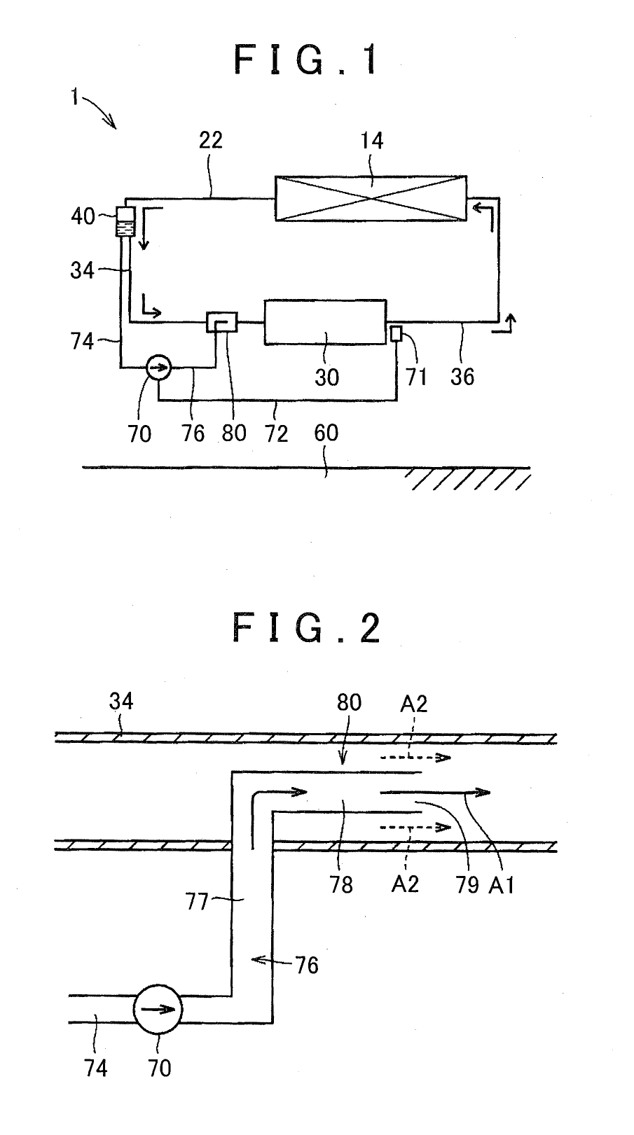

FIG. 1 is a schematic diagram illustrating a configuration of a cooling system 1. As shown in FIG. 1, the cooling system 1 has a heat exchanger 14, a cooling unit 30, and a gas-liquid separator 40. The cooling system 1 further includes a coolant passage 22 interconnecting between the heat exchanger 14 and the gas-liquid separator 40, a coolant passage 34 interconnecting between the gas-liquid separator 40 and the cooling unit 30, and a coolant passage 36 interconnecting between the cooling unit 30 and the heat exchanger 14. The cooling system 1 is configured by connecting the heat exchanger 14, the gas-liquid separator 40 and the cooling unit 30 by means of the coolant passages 22, 34 and 36. The coolant passage 22 may be regarded as the first passage of the present invention, and the coolant passage 34 may be regarded as a main passage of the present invention.

The coolant is circulated within the cooling system 1, passing through a coolant circulation channel in which the heat exchanger 14, the cooling unit 30 and the gas-liquid separator 40 are sequentially connected by means of the coolant passages 22, 34 and 36. The coolant circulating within the cooling system 1 may be, for example, carbon dioxide, a carbon hydride such as propane or isobutene, ammonia, a fluorocarbon, or water.

The heat exchanger 14 transforms coolant steam into coolant liquid by causing the heat of the coolant steam to dissipate to an external medium. The heat exchanger 14 includes a tube for circulating the coolant and fins for performing heat exchange between the coolant circulated through the tube and the air around the heat exchanger 14. The heat exchanger 14 carries out heat exchange between the coolant and cooling air supplied as natural wind generated by running of the vehicle or forced wind generated by a cooling fan such as a radiator fan for cooling the engine. The heat exchange by the heat exchanger 14 causes the coolant temperature to drop, whereby the coolant is liquefied.

The gas-liquid separator 40 is arranged on the passage of the coolant which flows from the heat exchanger 14 to the cooling unit 30. The gas-liquid separator 40 separates the coolant flowing out of the heat exchanger 14 into a gas-phase coolant and a liquid-phase coolant. There are stored, within the gas-liquid separator 40, coolant liquid as the liquid-phase coolant and coolant steam as the gas-phase coolant. The gas-liquid separator 40 is connected to the coolant passages 22 and 34 and to a suction passage 74 to be described later.

At the outlet of the heat exchanger 14, the coolant is in a wet steam state of the gas-liquid two-phase state in which saturated liquid and saturated steam are mixed. The coolant flowing out of the heat exchanger 14 is supplied to the gas-liquid separator 40 through the coolant passage 22. The coolant in the gas-liquid two-phase state flowing into the gas-liquid separator 40 from the coolant passage 22 is separated into a gas phase and a liquid phase in the inside of the gas-liquid separator 40. The gas-liquid separator 40 separates the coolant condensed by the heat exchanger 14 into a coolant liquid in the form of liquid and a coolant steam in the form of gas, and temporarily stores them.

The separated coolant liquid flows out of the gas-liquid separator 40 via the coolant passage 34. An end of the coolant passage 34 arranged in the liquid phase in the inside of the gas-liquid separator 40 defines an outlet for the liquid-phase coolant flowing out of the gas-liquid separator 40. In the inside of the gas-liquid separator 40, the coolant liquid accumulates in the lower side, whilst the coolant steam accumulates in the upper side. The end of the coolant passage 34 for introducing the coolant liquid out of the gas-liquid separator 40 is connected to the bottom of the gas-liquid separator 40. Only the coolant liquid is fed out of the gas-liquid separator 40 from the bottom side of the gas-liquid separator 40 and fed through the coolant passage 34. The coolant liquid thus fed out enables the gas-liquid separator 40 to separate the gas-phase coolant from the liquid-phase coolant in a reliable manner.

The cooling unit 30 includes hybrid vehicle equipment that is electric equipment mounted on the vehicle, and a cooling passage that is a piping through which the coolant circulates. The HV equipment is an example of the heat generation sources. One end of the cooling passage is connected to the coolant passage 34. The other end of the cooling passage is connected to the coolant passage 36. The coolant passage 34 is a passage for circulating the liquid-phase coolant from the gas-liquid separator 40 to the cooling unit 30. The coolant passage 36 is a passage for circulating the coolant from the cooling unit 30 to the heat exchanger 14.

The coolant liquid in the liquid phase of the coolant that has been subjected to gas-liquid separation in the gas-liquid separator 40 is circulated from the gas-liquid separator 40 to the cooling unit 30 via the coolant passage 34. The coolant circulated to the cooling unit 30 and flowing through the cooling passage cools the HV equipment that is a heat generation source by drawing heat from the HV equipment. The cooling unit 30 cools the HV equipment by using the liquid-phase coolant that is separated by the gas-liquid separator 40 and flows into the cooling passage via the coolant passage 34. In the cooling unit 30, the coolant flowing through the cooling passage exchanges heat with the HV equipment, whereby the HV equipment is cooled and the coolant is heated.

The cooling unit 30 is configured such that heat exchange between the HV equipment and the coolant can be performed in the cooling passage. In this embodiment, the cooling unit 30 has a cooling passage which is formed such that the outer periphery of the cooling passage is in direct contact, for example, with a casing of the HV equipment. The cooling passage has a portion adjacent to the HV equipment casing. The heat exchange between the HV equipment and the coolant flowing in the cooling passage can be performed in this portion of the cooling passage.

The HV equipment is cooled by being brought into direct contact with the outer periphery of the cooling passage forming a part of the passage for the coolant circulating in the cooling system 1. Since the HV equipment is arranged outside of the cooling passage, the HV equipment will not interfere with the flow of the coolant circulating within the cooling passage. Therefore, the HV equipment can be cooled without increasing the pressure loss affecting the coolant circulating in the cooling system 1.

Alternatively, the cooling unit 30 may be provided with any conventional heat pipe interposed between the HV equipment and the cooling passage. In this case, the HV equipment is connected to the outer periphery of the cooling passage via the heat pipe, so that the HV equipment is cooled by heat transfer from the HV equipment to the cooling passage via the heat pipe. The heat transfer efficiency between the cooling passage and the HV equipment can be improved by using the HV equipment as a heating unit for heating the heat pipe and using the cooling passage as a cooling unit for cooling the heat pipe, whereby the cooling efficiency for the HV equipment can be improved. The heat pipe may be, for example, a wick-type heat pipe.

The heat pipe ensures reliable heat transfer from the HV equipment to the cooling passage, and arrows the HV equipment to be spaced apart from the cooling passage, which eliminates the need of complicated arrangement of the cooling passage in order to establish direct contact between the HV equipment and the cooling passage. This improves the degree of freedom in arrangement of the HV equipment.

The HV equipment includes electric equipment which generates heat as a result of exchange of electric power. The electric equipment includes at least any one of an inverter for converting direct-current power into alternate-current power, a motor generator as a dynamo-electric machine, a battery as a electrical storage device, a converter for boosting a battery voltage, and a DC/DC converter for stepping down the battery voltage. The battery is a secondary battery such as a lithium ion battery or a nickel-metal hydride battery. A capacitor may be used in place of the battery.

The coolant passage 22 is a path to circulate the coolant from the heat exchanger 14 to the gas-liquid separator 40. The coolant flows between the heat exchanger 14 and the gas-liquid separator 40 via the coolant passage 22, from the outlet of the heat exchanger 14 toward the inlet of the gas-liquid separator 40. The coolant passage 34 is a path to circulate the coolant from the gas-liquid separator 40 to the cooling unit 30. The coolant flows between the gas-liquid separator 40 and the cooling unit 30 via the coolant passage 34, from the outlet of the gas-liquid separator 40 toward the inlet of the cooling unit 30. The coolant passage 36 is a path to circulate the coolant from the cooling unit 30 to the heat exchanger 14. The coolant flows between the cooling unit 30 and the heat exchanger 14 via the coolant passage 36, from the outlet of the cooling unit 30 toward the inlet of the heat exchanger 14.

The coolant is vaporized by receiving evaporative latent heat from the HV equipment when cooling the HV equipment. The coolant steam evaporated by heat exchange with the HV equipment flows to the heat exchanger 14 via the coolant passage 36. In the heat exchanger 14, the coolant steam is cooled and condensed by running wind of the vehicle or wind from an engine cooling radiator fan. Coolant liquid liquefied by the heat exchanger 14 returns to the cooling unit 30 via the coolant passages 22 and 34.

The cyclic passage passing through the cooling unit 30 and the heat exchanger 14 constitutes a heat pipe in which the HV equipment functions as a heating unit and the heat exchanger 14 functions as a cooling unit. Since the HV equipment can be cooled by means of the heat pipe, there is no need of providing special equipment for cooling the HV equipment, such as a water-circulating pump or a cooling fan. This makes it possible to reduce the number of components required for the cooling system 1 for the HV equipment and to simplify the system configuration, resulting in reduced manufacturing cost of the cooling system 1. In addition, there is no need of operating a power source for supplying power, for example, to a pump or cooling fan for cooling the HV equipment, and thus no power is consumed to operate the power source. As a result. the power consumption for cooling the HV equipment can be reduced.

FIG. 1 shows a ground surface 60. The cooling unit 30 is arranged at a lower position than the heat exchanger 14 in a vertical direction orthogonal to the ground surface 60. In the cyclic passage for circulating the coolant between the heat exchanger 14 and the cooling unit 30, the cooling unit 30 is arranged at a lower position while the heat exchanger 14 is arranged at an upper position. The heat exchanger 14 is placed at a higher position than the cooling unit 30.

With this arrangement, coolant steam heated and evaporated in the cooling unit 30 ascends in the cyclic passage to reach the heat exchanger 14. The coolant steam is then cooled and condensed in the heat exchanger 14 to become liquid coolant, which descends in the cyclic passage due to the effect of gravity and returns to the cooling unit 30. This means that a thermo-siphon-type heat pipe is formed by the cooling unit 30, the heat exchanger 14, and the coolant passages connecting therebetween. The formation of the heat pipe improves the heat transfer efficiency from the cooling unit 30 to the heat exchanger 14, and hence the HV equipment can be cooled efficiently without relying on any power.

Coolant liquid is stored in the inside of the gas-liquid separator 40 in a state of saturated liquid. The gas-liquid separator 40 functions as a liquid storage device for temporarily storing the coolant liquid that is the coolant in a liquid state in the inside thereof. The storage of a predetermined amount of the coolant liquid within the gas-liquid separator 40 makes it possible to maintain a flow rate of the coolant flowing from the gas-liquid separator 40 to the cooling unit 30 even during load fluctuation. Since the gas-liquid separator 40 has a liquid storage function and is able to act as a buffer against load fluctuation by absorbing the load fluctuation, stable cooling performance of the HV equipment can be obtained.

The passage for circulating the coolant flowing from the outlet of the gas-liquid separator 40 toward the inlet of the cooling unit 30 includes the coolant passage 34 interconnecting between the gas-liquid separator 40 and the cooling unit 30, a suction passage 74 for circulating the coolant liquid to a pump 70, and a discharge passage 76. The suction passage 74 may be regarded as a sub passage of the present invention.

The suction passage 74 is a passage which interconnects between the gas-liquid separator 40 and the pump 70 to circulate the liquid-phase coolant separated by the gas-liquid separator 40 to the pump 70. The coolant flows between the gas-liquid separator 40 and the pump 70 through the suction passage 74, from the outlet of the gas-liquid separator 40 toward the inlet of the pump 70.

An aspirator 80 is provided at a position where the coolant passage 34 meets the discharge passage 76. The discharge passage 76 is a passage which interconnects between the pump 70 and the aspirator 80 to circulate the coolant discharged from the pump 70 to the coolant passage 34 via the aspirator 80. The coolant flows between the pump 70 and the aspirator 80 through the discharge passage 76, from the outlet of the pump 70 toward the aspirator 80.

The passage extending from the gas-liquid separator 40 directly to the aspirator 80 and forming a part of the coolant passage 34 constitutes a first pathway. The passage including the suction passage 74, the pump 70 and the discharge passage 76 and extending from the gas-liquid separator 40 to the aspirator 80 via the pump 70 constitutes a second pathway. The first pathway and the second pathway are connected in parallel. The cooling system 1 has a plurality of passages extending from the gas-liquid separator 40 to the aspirator 80, and these passages are connected in parallel. The pump 70 is provided on the second pathway that is one of these passages connected in parallel.

A temperature sensor 71 for measuring temperature of the coolant flowing out of the cooling unit 30 is arranged downstream of the cooling unit 30 in the coolant flow direction. A cooling state of the HV equipment as a heat generation source is checked by using the temperature sensor 71 to acquire data relating to temperature of the coolant flowing out of the cooling unit 30. The data acquired by the temperature sensor 71 is transferred to the pump 70 through wiring 72. The pump 70 is controlled to be activated or stopped based on the data

When the temperature of the coolant flowing out of the cooling unit 30 is lower than a predetermined threshold, it is determined that the HV equipment is cooled sufficiently and the pump 70 is stopped. In contrast, when the temperature of the coolant flowing out of the cooling unit 30 is equal to or higher than the predetermined threshold, it is determined that the HV equipment is not cooled sufficiently and the pump 70 is activated. By activating the pump 70, the coolant liquid is forcibly supplied to the coolant passage 34 through the discharge passage 76, whereby the flow rate of the coolant liquid supplied from the flow coolant passage 34 to the cooling unit 30 is increased. The increase of the coolant liquid flowing through the cooling passage of the cooling unit 30 improves the cooling capacity for the HV equipment.

According to this configuration, when it is determined that the cooling capacity for the HV equipment is deficient during stoppage of the pump 70, the pump 70 can be immediately activated to forcibly transport the coolant liquid so that the liquid-phase coolant is supplied to the cooling unit 30. The cooling capacity for the HV equipment thus can be restored promptly to lower the temperature of the HV equipment, whereby overheating of the HV equipment can be effectively avoided. When the vehicle is climbing up a hill, for example, the load to the HV equipment may be increased abruptly and the amount of heat generated by the HV equipment may rise sharply. In such a case, the coolant liquid can be forcibly supplied to the cooling unit 30 by the pump 70 to enhance the cooling capacity for the HV equipment.

Since the pump 70 is arranged on the coolant passage connected in parallel with the coolant passage 34, the pump 70 will not obstruct, during stoppage thereof, the flow of the coolant flowing from the gas-liquid separator 40 to the cooling unit 30 through the coolant passage 34. Therefore, a flow of the coolant circulating within the cooling system 1 can be formed by using, as drive power, buoyant force of the coolant steam evaporated in the cooling unit 30 and gravity force acting on the coolant liquid liquefied in the heat exchanger 14, without the need of externally supplied power. Since heat can be transferred from the cooling unit 30 to the heat exchanger 14 based on the principle of heat pipe, the heat generation source can be reliably cooled by the naturally circulating cooling system without inhibiting the power saving.

When the generation source cannot be cooled sufficiently only by natural circulation of the coolant, the pump 70 is activated to increase the flow rate of the coolant liquid supplied to the cooling unit 30. For example, if an event such as an abrupt acceleration of the vehicles occurs that requires rapid and significant cooling when no heat is generated by the HV equipment due to stoppage of the motor and little coolant is flowing, the HV equipment will not be able to be cooled sufficiently only by natural circulation of the coolant due to delay in response of the coolant flow. In order to address such a problem, the pump 70 can be activated to compensate for the deficiency of the coolant and to enhance the capacity to cool the heat generation source. Accordingly, the deficiency in capability of cooling the heat generation source can be resolved promptly. Further, the provision of the pump 70 also improves the maximum cooling performance of the cooling system 1.

In addition to the temperature sensor 71 monitoring temperature at the outlet of the cooling unit 30, a pressure sensor can be arranged at the outlet of the cooling unit 30 to monitor pressure of the coolant flowing out of the cooling unit 30 in order to determine whether or not the coolant liquid need to be supplied to the cooling unit 30 by the pump 70. Not only data relating to temperature and pressure, but also any other data indicating a state of the coolant can be acquired with an appropriate sensor as long as the activation and stopping of the pump 70 can be controlled by acquiring the data indicating a state of the coolant downstream of the cooling unit 30 after cooling the HV equipment.

FIG. 2 is a schematic diagram illustrating in detail a configuration of the aspirator 80 shown in FIG. 1. As shown in FIG. 2, the discharge passage 76, in which the coolant liquid discharged from the pump 70 flows, has an uprising tube 77 and a parallel tube 78. The uprising tube 77 is arranged so as to extend across (typically, orthogonally to) the direction in which the coolant passage 34 extends. The uprising tube 77 is arranged to extend between the inside and the outside of the coolant passage 34 passing through a wall of the coolant passage 34. The parallel tube 78 is arranged in the inside of the coolant passage 34. The parallel tube 78 is arranged in parallel with the direction in which the coolant passage 34 extends.

The solid-line arrow A1 in FIG. 2 indicates the flow of the coolant liquid which is discharged from the pump 70, flows in the inside of the parallel tube 78, and flows into the coolant passage 34 through an opening 79. The dashed-line arrows A2 in FIG. 2 indicate flow of the coolant liquid which flows from the gas-liquid separator 40 into the coolant passage 34 and reaches the aspirator 80. The parallel tube 78 is positioned with respect to the coolant passage 34 such that the flow direction of the coolant flowing in the inside of the parallel tube 78 is parallel with the flow direction of the coolant flowing in the inside of the coolant passage 34.

The parallel tube 78 functions as a flow regulating unit for regulating a flow direction of the coolant. When the parallel tube 78 is arranged adequately, the flow direction of the coolant that is discharged from the pump 70 and returns to the coolant passage 34 is guided so that the coolant flows along the flow direction of the coolant that flows from the gas-liquid separator 40 directly to the cooling unit 30 through the coolant passage 34. By regulating the flow direction of the coolant returning to the coolant passage 34 with the flow regulating unit, it is made possible to suppress the pressure loss that occurs when the coolant discharged from the pump 70 flows to the coolant passage 34. This further enhances the effect of increasing the flow rate of the coolant liquid to the cooling unit 30 by activation of the pump 70. In addition, the effect of promoting the flow of the coolant liquid within the coolant passage 34 due to viscosity of the coolant ejected from the discharge passage 76 into the coolant passage 34 can also be enhanced further.

The flow regulating unit may have any other configuration than the one described above. For example, a check valve may be provided in the coolant flow and upstream of the merging point between the coolant passage 34 and the discharge passage 76. In this embodiment, however, the flow direction of the coolant returning to the coolant passage 34 is guided by arranging the parallel tube 78 to extend along the flow direction of the coolant in the coolant passage 34 so that the coolant is caused to enter the coolant passage 34 through the opening 79 on the downstream side in the flow direction of the coolant. In this manner, the configuration can be made simple and low-cost. Moreover, the flow regulating unit can be formed in an adequate manner since the increase in the pressure loss of the coolant circulating in the coolant passage 34 can be suppressed.

The aspirator 80 is arranged at a position where the coolant discharged from the pump 70 returns to the coolant passage 34. The coolant liquid is ejected from the parallel tube 78 in the discharge passage 76 into the coolant passage 34 to form a jet flow in the coolant passage 34. This jet flow generates negative pressure around the jet flow in the inside of the coolant passage 34. The generation of the negative pressure allows the aspirator 80 to achieve its function of creating a depressurized state in the coolant passage 34 by utilizing the flow of the coolant liquid.

The coolant liquid in the coolant passage 34 flows toward a negative pressure generated region formed by the aspirator 80, in a rightward direction as viewed in FIG. 2. The flow of the coolant liquid in the coolant passage 34 is promoted by the flow of the coolant. Additionally, the flow of the coolant liquid in the coolant passage 34 is also promoted by viscosity of the jet flow ejected from the parallel tube 78. A flow of coolant flowing through the inside of the coolant passage 34 toward the cooling unit 30 is formed by using, as driving flow, the coolant ejected from the parallel tube 78 in the discharge passage 76. This flow of the coolant in the coolant passage 34 becomes a flow of the coolant that will naturally circulate within the cooling system 1.

Thus, the driving flow can be generated in the coolant passage 34 by activating the pump 70, whereby the flow rate of the coolant flowing from the coolant passage 34 to the cooling unit 30 can be ensured. When the pump 70 is stopped afterward, the system is allowed to smoothly transition into a naturally circulating cooling system since the flow of the coolant circulating in the cooling system 1 has already been formed.

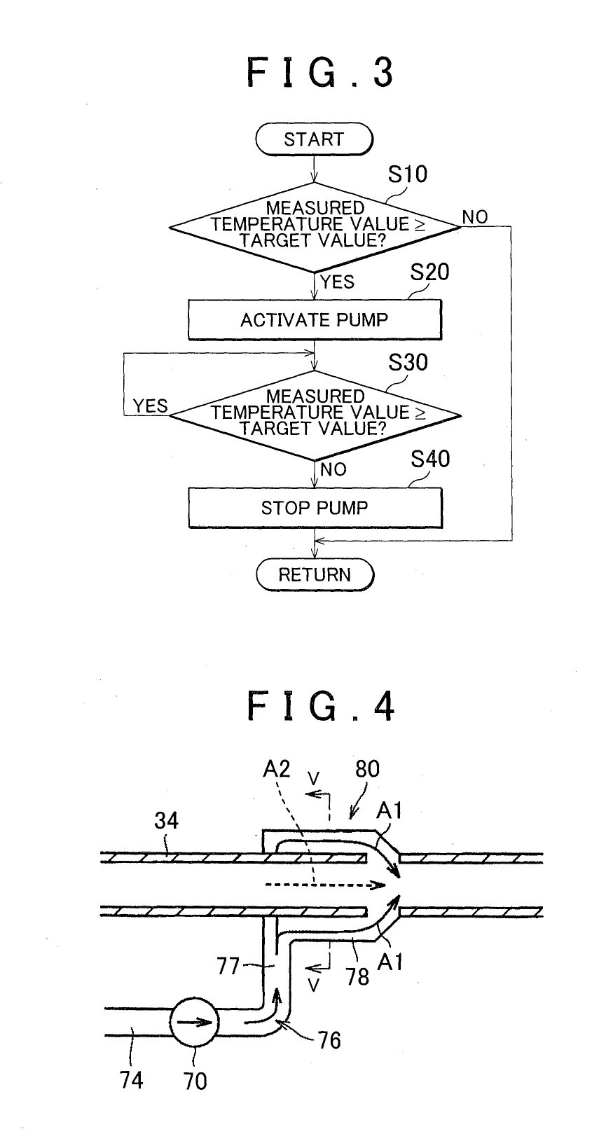

FIG. 3 is a flowchart illustrating operation control for the pump 70. Referring to FIG. 3, description will be made on operation control for the pump 70 interlocked with coolant temperature at the outlet of the cooling unit 30 acquired by the temperature sensor 71.

Firstly, in step (S10), temperature of the coolant at the outlet of the cooling unit 30 after cooling, the HV equipment is detected with the temperature sensor 71. It is determined whether or not the measured value of coolant temperature is equal to or higher than a targeted coolant temperature threshold. When the measured value of coolant temperature is determined to be equal to or higher than the target value, the control processing proceeds to step (S20) in which the pump 70 is activated so that the coolant liquid is discharged from the pump 70 into the discharge passage 76. The operation of the pump 70 gives energy to the coolant liquid whereby the coolant liquid is transferred to the cooling unit 30 via the discharge passage 76 and the coolant passage 34.

Next, in step (S30), it is determined again whether or not the measured value of coolant temperature is equal to or higher than the targeted coolant temperature threshold. If the measured value of coolant temperature is determined to be still equal to or higher than the target value, the operation of the pump 70 is continued. If the measured temperature value of the coolant at the outlet of the cooling unit 30 is determined to be lower than the targeted value, then the pump 70 is stopped in step (S40). This means that the operation of the pump 70 is continued until the measured temperature value of the coolant at the outlet of the cooling unit 30 is determined to have dropped lower than the target value.

This control flow is then returned again to step (S10) in which coolant temperature at the outlet of the cooling unit 30 is monitored. When it is determined in step (S10) that the measured value of coolant temperature is lower than the target value, the control flow is also returned so that the monitoring of coolant temperature at the outlet of the cooling unit 30 is continued.

The pump 70 is operated only when it is determined that the HV equipment is not cooled sufficiently as a result of the monitoring of the state of the coolant at the outlet of the cooling unit 30, whereas the pump 70 is not operated when it is determined that HV equipment is cooled sufficiently. The pump 70 can be activated or stopped by such simple control as described above. In addition, the configuration for providing the pump 70 is also a very simple and compact configuration consisting of the pump 70 itself, the suction passage 74 for supplying the coolant liquid to the pump 70, and the discharge passage 76 for returning the coolant liquid from the pump 70 to the coolant passage 34. Thus, this simple and low-cost configuration makes it possible to combine the cooling system for naturally circulating the coolant within the cooling system 1 with the cooling system for forcibly circulating the coolant with use of the pump 70, and allows users to enjoy merits of both systems.

According to this embodiment of the invention, as shown in FIG. 1, the upstream end of the suction passage 74 is connected to a liquid reservoir for accommodating the liquid-phase coolant in the gas-liquid separator 40. Such a configuration makes it possible to cause the gas-liquid separator 40 accommodating a sufficient amount of liquid-phase coolant to discharge the coolant liquid directly to the suction passage 74, and to reliably supply the coolant liquid to the pump 70. Therefore, possible troubles in the pump 70 that is specified to transfer liquid can be suppressed. Further, the suction passage 74 may be branched in the middle of the coolant passage 34. In this case, the length of the suction passage 74 can be shortened, which makes it possible to realize a simple and low-cost configuration and makes it easy to lay out the suction passage 74.

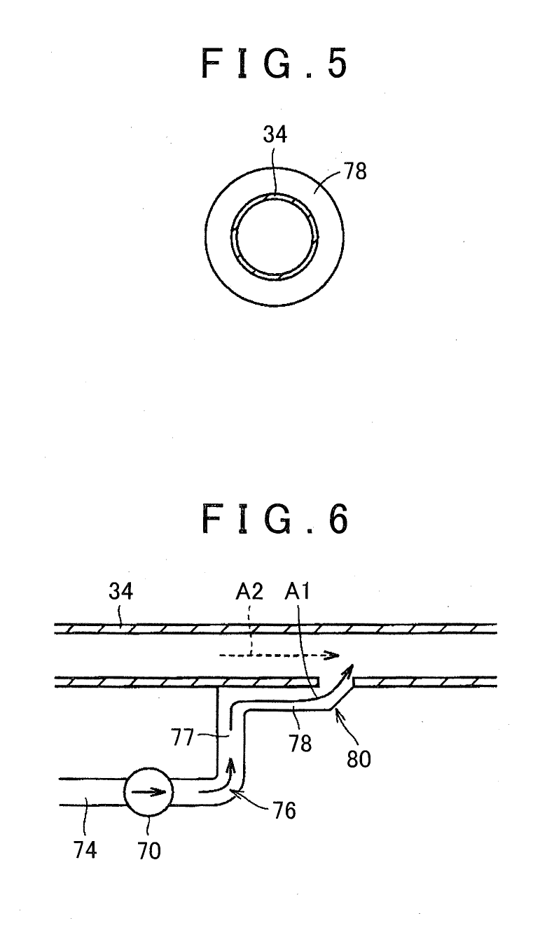

FIG. 4 is a schematic diagram illustrating in detail a configuration of the aspirator 80 according to a modification example. FIG. 5 is a schematic cross-sectional view of the aspirator 80 taken along the line V-V in FIG. 4. Although in the aspirator 80 shown in FIG. 2, the uprising tube 77 and the parallel tube 78 of the discharge passage 76 are arranged in the inside of the coolant passage 34, the invention is not limited to this configuration. As shown in FIG. 4, for example, the parallel tube 78 may be formed to have a greater diameter than the coolant passage 34 so as to circumferentially surround the coolant passage 34, while the coolant passage 34 may be inserted to passage through the inside of the parallel tube 78.

This configuration is also able to ensure a sufficient flow rate of the coolant flowing from the coolant passage 34 to the cooling unit 30 at the activation of the pump 70. Further, the flow of the coolant liquid within the coolant passage 34 can be promoted by negative pressure that is generated in the coolant passage 34 by jet flow of the coolant liquid discharged from the pump 70 through the parallel tube 78 into the coolant passage 34. The formation of the flow of the coolant circulating in the inside of the cooling system 1 enables smooth transition to the naturally circulating cooling system when the pump 70 is stopped.

Furthermore, as a result of arranging the parallel tube 78 outside the coolant passage 34, obstacles present in the coolant passage 34 can be reduced, which in turn reduces pressure loss of the flow of the coolant liquid naturally circulating in the cooling system 1. Consequently, a natural circulation cooling system in which the flow of the coolant liquid is further facilitated can be provided.

FIG. 6 is a schematic diagram illustrating in detail a configuration of the aspirator 80 according to another modification example. As shown in FIG. 6, the parallel tube 78 may be arranged outside the coolant passage 34 along the direction in which the coolant passage 34 extends, so that a flow of coolant liquid is formed which is ejected from the parallel tube 78 into the coolant passage 34 through an opening formed in a part of the coolant passage 34. This configuration is also able to provide the same effects as the aspirator 80 according to the aforementioned modification example.

The foregoing description of the embodiments has been made in terms of the cooling system 1 for cooling electric equipment mounted on a vehicle, taking HV equipment as an example of such electric equipment. However, the electric equipment is not limited to an inverter, a motor generator or the like exemplified in the above, but may be any electric equipment as long as it generates heat by operation thereof When there are a plurality of pieces of electric equipment to be cooled, these pieces of electric equipment desirably have a common temperature range that is set as a target cooling temperature range. The target cooling temperature range is a temperature range that is adequate as temperature environment for operating the electric equipment.

The cooling system 1 may be provided alone as an apparatus for cooling a heat generation source with the cooling unit 30. Alternatively, the cooling system 1 may be incorporated in a steam compression refrigeration cycle having a compressor, a condenser, a decompressor, and an evaporator and used as room air conditioner, so that a system is configured which is capable of reliably cooling a heat generation source during operation and suspension of the compressor. In this case, a condenser may be used as the heat exchanger 14. When a plurality of condensers are provided, the first upstream condenser is used as the heat exchanger 14 and the cooling unit 30 is arranged while a coolant passage is provided to connect the upstream of the first condenser with the downstream of the cooling unit 30, so that the heat generation source is cooled with the coolant circulating through the condensers.

In the above-described embodiment, the suction passage 74 is connected to the coolant passage 34, and the coolant flows into the coolant passage 34 from the suction passage 74 via the aspirator 80. As a modification example, a passage through which a coolant discharged from the gas-liquid separator 40 flows may directly connected to the cooling unit 30 so that the coolant discharged from the gas-liquid separator 40 flows into the cooling unit 30.

Although the foregoing description has been made of exemplary embodiments of the invention, it should be understood that these embodiments disclosed herein are illustrative only and not restrictive in all respects. The scope of the invention is defined not by the foregoing description but by appended claims, and all equivalents to the scope of the claims and all changes and modifications within the scope will be construed as being included in the invention.

The cooling system according to the invention is applicable particularly advantageously to cooling of electric equipment in vehicles such as HVs, fuel cell vehicles, and electric vehicle having electric equipment such as motor generators and inverters mounted thereon.

1. A cooling system for cooling a heat generation source, comprising:
a cooling unit that is configured to cool the heat generation source by a coolant flowing through the cooling unit;
a heat exchanger that is configured to perform heat exchange between the coolant and outside air;
a liquid storage device that is configured to store the coolant in a liquid state;
a first passage for the coolant that connects between the heat exchanger and the liquid storage device;
a second passage for the coolant that connects between the liquid storage device and the cooling unit, and that comprises a main passage that connects between the liquid storage device and the cooling unit and a sub passage, at least part of which is separate from the main passage; and
a pump that is provided on the sub passage.

2. The cooling system according to claim 1, wherein the liquid storage device functions as a gas-liquid separator for separating the coolant into a gas-phase coolant and a liquid-phase coolant.

3. The cooling system according to claim 1, wherein one end of the sub passage is connected to the liquid storage device and the other end of the sub passage is connected to the main passage.

4. The cooling system according to claim 3, further comprising a flow guide unit that is configured to guide a flow direction of the coolant that is discharged from the pump and flows into the main passage, to a direction from the liquid storage device toward the cooling unit.

5. The cooling system according to claim 3, further comprising an aspirator arranged at a position where the coolant discharged from the pump flows into the main passage,
wherein the coolant flows into the main passage from the sub passage via the aspirator.

6. The cooling system according to claim 1, further comprising a sensor for acquiring data indicating a state of the coolant after the coolant flows through the cooling unit to cool the heat generation source,
wherein the pump is activated or stopped based on the data.

7. The cooling system according to claim 6, wherein:
the state of the coolant is a temperature of the coolant and
the pump is stopped when the temperature of the coolant after the coolant flows through the cooling unit to cool the heat generation source is below a predetermined threshold; and
the pump is activated when the temperature of the coolant after the coolant flows through the cooling unit to cool the heat generation source is equal to or higher than the predetermined threshold.
